(19) United States
(12) Patent Application Publication
(10) Pub. No.: US 2004/0107891 A1
(43) Pub. Date: Jun. 10, 2004

(54) Method for producing group III nitride compound semiconductor substrate

(75) Inventors: Seiji Nagai, Nishikasugai-gun (JP); Masayoshi Koike, Ichinomiya-shi (JP)

Correspondence Address: MCGINN & GIBB, PLLC, 8321 OLD COURTHOUSE ROAD, SUITE 200, VIENNA, VA, 22182-3817, US

(73) Assignee: Toyoda Gosei Co., Ltd., Aichi-Ken (JP)

(21) Appl. No.: 10/662,809

(22) Filed: Sep. 16, 2003

(30) Foreign Application Priority Data
Sep. 17, 2002 (JP) P2002-269634

(51) Int. Cl. C30B 1/00

(52) U.S. Cl. 117/2

(57) ABSTRACT

On an upper surface of a silicon (Si) substrate, an Al_{0.2}Ga_{0.8}N layer having a film thickness of 0.2 μm to 0.3 μm and a GaN layer having a film thickness of 0.5 μm are formed successively. The resulting substrate is set in a halide VPE apparatus so that the resulting substrate can be independently etched with HCl gas from a rear surface of the resulting substrate. While a GaN layer is epitaxially grown on the GaN layer at 900° C. by a halide vapor-phase epitaxy method, the silicon (Si) substrate, the Al_{0.2}Ga_{0.8}N layer and the GaN layer are removed from the rear surface by gas etching. In this manner, the GaN layer having a film thickness of about 50 μm is obtained. While a GaN layer is epitaxially grown on the GaN layer at 1050° C. by a halide vapor-phase epitaxy method, the GaN layer is removed from the rear surface by gas etching. Finally, a substrate made of the GaN layer with a film thickness of 200 μm and free from any warp and any crack is obtained.

The present application is based on Japanese Patent Application No. 2002-269634, which is incorporated herein by reference.

### BACKGROUND OF THE INVENTION

1. Field of the Invention

The present invention relates to a method for producing a Group III nitride compound semiconductor substrate having a thickness allowed to be handled as an epitaxially grown substrate. Group III nitride compound semiconductors are represented by the general formula AlₓGa_{y}In_{1-x-y}N (0≦x≦1, 0≦y≦1, 0≦x+y≦1) which includes binary compounds such as AlN, GaN and InN, ternary compounds such as AlₓGa_{y}N, AlₓIn₁₋ₓN and GaₓIn₁₋ₓN (0<x<1 each), and quaternary compounds such as AlₓGa_{y}In_{1-x-y}N (0<x<1, 0<y<1, 0<x+y<1). Incidentally, when no particular limitation is given in this specification, the term “Group III nitride compound semiconductor” may mean a Group III nitride compound semiconductor doped with impurities to form a p-type or an n-type as its conduction type.

2. Description of the Related Art

It is necessary to use a substrate for epitaxial growth of a Group III nitride compound semiconductor, for example, represented by the general formula AlₓGa_{y}In_{1-x-y}N (0≦x≦1, 0≦y≦1, 0≦x+y≦1). A Group III nitride compound semiconductor substrate having a thickness allowed to be handled is however unavailable commercially. Therefore, an inexpensive substrate such as a sapphire substrate, a silicon carbide (SiC) substrate or a silicon (Si) substrate is used as a substrate different in kind from the Group III nitride compound semiconductor (the substrate hereinafter referred to as different-kind substrate).

The inexpensive different-kind substrate is however largely different in lattice constant from the Group III nitride compound semiconductor. For this reason, a so-called buffer layer is generally formed on the different-kind substrate before the Group III nitride compound semiconductor is epitaxially grown. Even in this case, however, when the temperature is restored to room temperature after epitaxial growth at a very high temperature of not lower than 1000° C., a large amount of heat stress is generated because of the difference in thermal expansion coefficient between the different-kind substrate and the Group III nitride compound semiconductor. That is, even in the case where good epitaxial growth can be performed at a high-temperature stage, a large number of crystal defects or cracks occur in the inside of the different-kind substrate and in the inside of the Group III nitride compound semiconductor layer because of the large difference in thermal expansion coefficient between the different-kind substrate and the Group III nitride compound semiconductor when the different-kind substrate with the Group III nitride compound semiconductor layer is cooled to room temperature.

Furthermore, even in the middle of epitaxial growth at a temperature near 1000° C., stress is generated between the different-kind substrate and the Group III nitride compound semiconductor because of the difference in lattice constant. A warp with a curvature radius of about 50 cm remains in the Group III nitride compound semiconductor epitaxially grown under the stress even in the case where the rear surface of the substrate is removed by etching or the like after the decrease in temperature. What is meant by this curvature radius is that the quantity of a warp of a circumferential edge portion relative to a center portion, for example, in a disk-like substrate having a diameter of 5 cm, reaches 0.6 mm viewed from a plane tangential to the center portion.

Furthermore, the present inventors have found that generation of stress, for example, in the case where the substrate is silicon (Si), causes chemical reaction of silicon with the Group III nitride compound semiconductor while the Group III nitride compound semiconductor is epitaxially grown.

### SUMMARY OF THE INVENTION

The invention provides a method of producing a Group III nitride compound semiconductor substrate, including: the first layer forming step of forming a first Group III nitride compound semiconductor layer by a halide vapor-phase epitaxy method (i) directly on a silicon (Si) substrate or (ii) after forming a buffer layer on said silicon substrate; and the silicon substrate removing step of removing almost the whole of the silicon substrate from a rear surface by etching after the completion of the first layer forming step or during the first layer forming step. Preferably, the method according to the invention further includes: the second layer forming step of forming a second Group III nitride compound semiconductor layer by a halide vapor-phase epitaxy method after the silicon substrate removing step. The composition of the first Group III nitride compound semiconductor layer may be equal to or different from that of the second Group III nitride compound semiconductor layer. Each of the first and second Group III nitride compound semiconductor layers may contain impurities. The impurities contained in the first and second Group III nitride compound semiconductor layers respectively maybe equal to or different from each other in terms of kind and concentration. When the buffer layer is formed, the method for forming the buffer layer per se can be selected at option. The buffer layer is not limited to a so-called amorphous layer, that is, the term “buffer layer” used herein simply means a “layer-growth starting layer”. The halide vapor-phase epitaxy method is provided for spraying hydrogen chloride (HCl) onto a single element such as gallium (Ga) held at a high temperature to thereby sublime chloride (GaCl, GaCl₃) to be led to the epitaxial substrate.

Preferably, the method according to the invention further includes: the first layer removing step of removing a large part of the first Group III nitride compound semiconductor layer from the rear surface by etching after the completion of the second layer forming step or during the second layer forming step.

Preferably, the method according to the invention further includes: the etching stopper layer forming step of forming, as an etching stopper layer, a Group III nitride compound semiconductor layer containing a larger amount of aluminum than an amount of aluminum contained in each of the first and second Group III nitride compound semiconductor layers before the second layer forming step, wherein the first layer removing step is provided for completely removing the first Group III nitride compound semiconductor layer.

Preferably, in the method according to the invention, the first layer forming step is carried out at a temperature of not higher than 1000° C. whereas the second layer forming step is carried out at a temperature of not lower than 1000° C. Preferably, in the method according to the invention, the film thickness of the first Group III nitride compound semiconductor layer formed in the first layer forming step is not larger than 200 μm. Preferably, in the method according to the invention, the buffer layer is formed as a Group III nitride compound semiconductor layer containing aluminum or as a multi-layer including at least one Group III nitride compound semiconductor layer containing aluminum.

When a silicon substrate is etched from a rear surface after a first Group III nitride compound semiconductor layer is epitaxially grown on an upper surface of the silicon substrate, stress between the silicon substrate and the first Group III nitride compound semiconductor layer after epitaxial growth can be relaxed so that the stress is finally substantially absent. Or when the silicon substrate is etched from the rear surface while the first Group III nitride compound semiconductor layer is epitaxially grown on an upper surface of the silicon substrate, the first Group III nitride compound semiconductor layer can be formed in the condition that stress between the silicon substrate and the first Group III nitride compound semiconductor layer during epitaxial growth is suppressed so that the stress is finally substantially absent. In this case, stress applied on the second Group III nitride compound semiconductor layer formed after almost perfect removal of the silicon substrate can be made very low or low enough to be ignorable. In this manner, even in the case where the film thickness of the second Group III nitride compound semiconductor layer portion is made large, the second Group III nitride compound semiconductor layer portion can be used as an independent Group III nitride compound semiconductor substrate free from any warp and any crack.

When a large part of the first Group III nitride compound semiconductor layer is removed from the rear surface by etching after or during epitaxial growth of the second Group III nitride compound semiconductor layer, the first Group III nitride compound semiconductor layer warped by stress generated between the silicon substrate and the first Group III nitride compound semiconductor layer can be removed so that a Group III nitride compound semiconductor substrate of higher quality can be obtained. In this case, when a Group III nitride compound semiconductor layer containing a larger amount of aluminum than the amount of aluminum contained in each of the first and second Group III nitride compound semiconductor layers is formed between the first and second Group III nitride compound semiconductor layers, the Group III nitride compound semiconductor layer containing a larger amount of aluminum serves as an etching stopper layer. As a result, a Group III nitride compound semiconductor substrate having a smooth rear surface can be obtained.

Preferably, the first layer forming step is carried out at a temperature of not higher than 1000° C. whereas the second layer forming step is carried out at a temperature of not lower than 1000° C. More preferably, the first layer forming step is carried out at a temperature of from 800° C. to 900° C. In the first layer forming step, the silicon substrate has not been removed yet. Accordingly, in the first layer forming step, a temperature as low as possible needs to be used so that chemical reaction between the silicon substrate and the Group III nitride compound semiconductor layer can be restrained from being caused by stress. On the other hand, in the second layer forming step, because almost the whole of the silicon substrate has been already removed, stress per se is not generated or stress very low to prevent the chemical reaction is generated. Accordingly, in the second layer forming step, it is preferable that the Group III nitride compound semiconductor is epitaxially grown in an optimum condition for epitaxial growth.

Preferably, the film thickness of the first Group III nitride compound semiconductor layer formed in the first layer forming step is selected to be not larger than 200 μm, especially not larger than 100 μm. The lower limit of the film thickness is not smaller than 10 μm, preferably not smaller than 30 μm. This is because cracks occur during etching if the film thickness is too small. In the first layer forming step, the silicon substrate has not been removed yet. Accordingly, in the first layer forming step, the chemical reaction between the silicon substrate and the Group III nitride compound semiconductor layer needs to be restrained from being caused by stress. From this point of view, when the first Group III nitride compound semiconductor layer is formed thinly, stress can be restrained from being generated. When the buffer layer is formed, it is preferable from the point of view of affinity to the silicon substrate that a Group III nitride compound semiconductor layer containing aluminum or a mixture layer including the aluminum-containing Group III nitride compound semiconductor layer and another Group III nitride compound semiconductor layer is used as the buffer layer.

### BRIEF DESCRIPTOIN OF THE DRAWINGS

In the accompanying drawings:

FIGS. 1A to 1F are procedural views showing a method for producing a Group III nitride compound semiconductor substrate according to a first specific embodiment of the invention; and

FIGS. 2A to 2D are procedural views showing a second half of a method for producing a Group III nitride compound semiconductor substrate according to a third specific embodiment of the invention.

### DETAILED DESCRIPTION OF THE PREFERRED EMBODIMENTS

Embodiments of the invention will be described below with reference to the drawings. Incidentally, the invention is not limited to the following embodiments.

[First Embodiment]

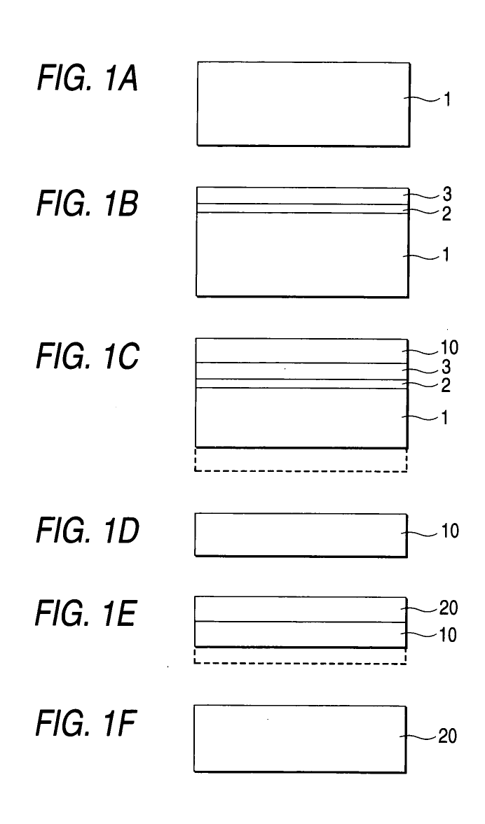

First, a preheated silicon (Si) substrate 1 having a (111) face as a principal surface was prepared (FIG. 1A). Then, an Al_{0.2}Ga_{0.6}N layer 2 having a film thickness of 0.2 μm to 0.3 μm and a GaN layer 3 having a film thickness of 0.5 μm were formed successively on an upper surface of the silicon (Si) substrate 1 by MOCVD (FIG. 1B). On this occasion, trimethyl aluminum (Al(CH₃)3), trimethyl gallium (Ga (CH₃)3) and ammonia (NH₃) were used as raw materials. In this embodiment, the Al_{0.2}Ga_{0.8}N layer 2 and the GaN layer 3 were equivalent to the buffer layer (layer-growth starting layer).

Then, the silicon (Si) substrate 1 having the Al_{0.2}Ga_{0.8}N layer 2 and the GaN layer 3 formed thereon was set in a halide VPE apparatus so that the silicon (Si) substrate 1 could be etched with HCl gas independently from a rear surface of the silicon (Si) substrate 1. The temperatures on both the halide vapor-phase epitaxy side and the gas etching side of the halide VPE apparatus were selected to be 900° C. While halide vapor-phase epitaxial growth of a GaN layer 10 was performed at 900° C. from an upper surface of the silicon (Si) substrate 1 by GaCl and ammonia produced from metallic gallium and hydrogen chloride in this manner (first layer forming step), a rear surface of the silicon (Si) substrate 1 was gas-etched with hydrogen chloride (silicon substrate removing step) (FIG. 1C) After the silicon (Si) substrate 1 was gas-etched completely, gas etching was still continued so that the Al_{0.2}Ga_{0.8}N layer 2 and the GaN layer 3 formed by MOCVD were further removed. In this manner, the GaN layer 10 having a film thickness of about 50 μm was obtained (FIG. 1D) Incidentally, on this occasion, there was neither decrease of the temperature nor taking of the resulting substrate from the halide VPE apparatus.

Then, the substrate temperature was increased to 1050° C. While halide vapor-phase epitaxial growth of a GaN layer 20 was performed at 1050° C. from an upper surface of the GaN layer 10 by GaCl and ammonia produced from metallic gallium and hydrogen chloride (second layer forming step), the GaN layer 10 was gas-etched with hydrogen chloride from the rear surface (first layer removing step) (FIG. 1E). Finally, the GaN layer 10 grown at 900° C. by halide vapor-phase epitaxy was removed completely, so that a substrate made of the GaN layer 20 grown at 1050° C. by halide vapor-phase epitaxy was obtained. The substrate made of the GaN layer 20 grown at 1050° C. by halide vapor-phase epitaxy had a film thickness of 200 μm and a curvature radius of about 5 m. The quantity of a warp of a circumferential edge portion relative to a center portion of the substrate was only 0.06 mm viewed from a plane tangential to the center portion when calculated in terms of a disk-like substrate having a diameter of 5 cm. That is, the substrate made of the GaN layer 20 grown at 1050° C. by halide vapor-phase epitaxy was a very flat substrate substantially free from any warp (FIG. 1F) According to the above embodiment, the GaN layer 20 is formed on the GaN layer 10 after the silicon (Si) substrate 1 is etched. However, it is not essential to form the GaN layer 20 after the substrate etching step. A single layer of the GaN layer 10 may be used as a substrate for a Group III nitride compound semiconductor. The GaN layer 10 may be subject to grinding to be flattened before it is used as the substrate.

[Second Embodiment]

After the GaN layer 10 having a film thickness of about 50 μm was obtained in the first embodiment (FIG. 1D), the substrate temperature was increased to 1050° C. so that a GaN layer 20 having a film thickness of 200 μm was epitaxially grown in the same manner as in the first embodiment except that the GaN layer 10 was not etched. The substrate having a film thickness of 250 μm and made of the GaN layers 10 and 20 was a substrate of excellent quality free from any crack.

[Third Embodiment]

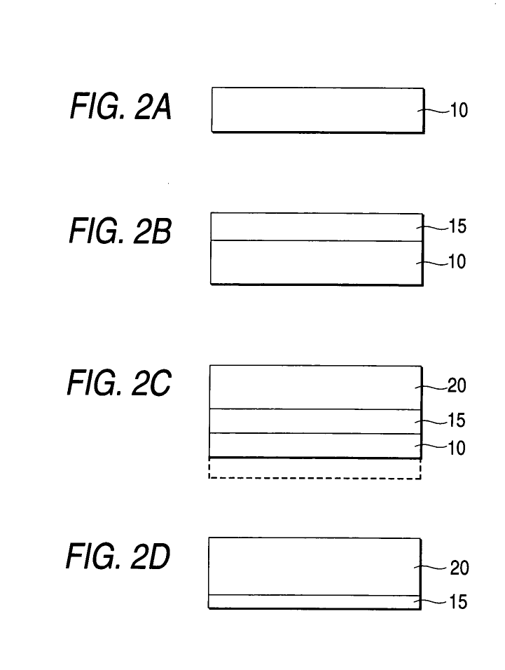

After the GaN layer 10 having a film thickness of about 50 μm was obtained in the first embodiment (FIG. 2A, equivalent to FIG. 1D), an Al_{0.4}Ga_{0.6}N layer 15 having a film thickness of about 10 μm was formed as an etching stopper layer (FIG. 2B). Then, while halide vapor-phase epitaxial growth of a GaN layer 20 was performed at 1050° C. on the Al_{0.4}Ga_{0.6}N layer 15 formed on an upper surface of the GaN layer 10, the GaN layer 10 was gas-etched with hydrogen chloride from the rear surface in the same manner as in the first embodiment (FIG. 2C). The GaN layer 10 was removed completely though part of the Al_{0.4}Ga_{0.6}N layer 15 remained. In this manner, a substrate made of the GaN layer 20 grown at 1050° C. by halide vapor-phase epitaxy was obtained. The substrate made of the GaN layer 20 was a very flat substrate substantially free from any warp and good in flatness of its rear surface (FIG. 2D) The reason why the substrate was good in flatness of its rear surface was as follows. Because the rate of etching the Al_{0.4}Ga_{0.6}N layer 15 with HCl was lower than the rate of etching the GaN layer 10 with HCl, the etching rate of the Al_{0.4}Ga_{0.6}N layer 15 was reduced evenly. Accordingly, surface roughness caused by unevenness in the etching rate of the GaN layer 10 was relaxed.

Although the embodiments have been described mainly on the case where a GaN substrate is obtained, the invention may be also applied to a method for producing a Group III nitride compound semiconductor substrate having any composition. Impurities may be introduced at option in the second layer forming step. The Group III nitride compound semiconductor formed in the first layer forming step may be different in composition from the Group III nitride compound semiconductor formed in the second layer forming step. Whether impurities are to be added or not to be added can be decided freely. The kind and concentration of impurities added to the Group III nitride compound semiconductor formed in the first layer forming step may be equal to or different from those of impurities added to the Group III nitride compound semiconductor formed in the second layer forming step.

Although the invention has been described in its preferred form with a certain degree of particularity, it is understood that the present disclosure of the preferred form can be changed in the details of construction and in the combination and arrangement of parts without departing from the spirit and the scope of the invention as hereinafter claimed.

What is claimed is:

1. A method of producing a Group III nitride compound semiconductor substrate, comprising:
the first layer forming step of forming a first Group III nitride compound semiconductor layer by a halide vapor-phase epitaxy method (i) directly on a silicon (Si) substrate or (ii) after forming a buffer layer on said silicon substrate; and
the silicon substrate removing step of removing almost the whole of said silicon substrate from a rear surface by etching after the completion of the first layer forming step or during the first layer forming step.

2. A method of producing a Group III nitride compound semiconductor substrate according to claim 1, further comprising: the second layer forming step of forming a second Group III nitride compound semiconductor layer by a halide vapor-phase epitaxy method after the silicon substrate removing step

3. A method of producing a Group III nitride compound semiconductor substrate according to claim 2, further comprising: the first layer removing step of removing a large part of said first Group III nitride compound semiconductor layer from said rear surface by etching after the completion of the second layer forming step or during the second layer forming step.

4. A method of producing a Group III nitride compound semiconductor substrate according to claim 3, further comprising: the etching stopper layer forming step of forming, as an etching stopper layer, a Group III nitride compound semiconductor layer containing a larger amount of aluminum than an amount of aluminum contained in each of the first and second Group III nitride compound semiconductor layers before the second layer forming step, wherein the first layer removing step is provided for completely removing the first Group III nitride compound semiconductor layer.

5. A method of producing a Group III nitride compound semiconductor substrate according to claim 2, wherein the first layer forming step is carried out at a temperature of not higher than 1000° C. whereas the second layer forming step is carried out at a temperature of not lower than 1000° C.

6. A method of producing a Group III nitride compound semiconductor substrate according to claim 1, wherein a film thickness of said first Group III nitride compound semiconductor layer formed in the first layer forming step is not larger than 200 μm.

7. A method of producing a Group III nitride compound semiconductor substrate according to claim 1, wherein said buffer layer is formed as a Group III nitride compound semiconductor layer containing aluminum or as a multi-layer including at least one Group III nitride compound semiconductor layer containing aluminum.

8. A method of producing a Group III nitride compound semiconductor substrate, comprising:
the first layer forming step of forming a first Group III nitride compound semiconductor layer by a halide vapor-phase epitaxy method (i) directly on a silicon (Si) substrate or (ii) after forming a buffer layer on said silicon substrate; and
the silicon substrate removing step of removing almost the whole of said silicon substrate from a rear surface by etching after the completion of the first layer forming step or during the first layer forming step;
wherein the first layer forming step is carried out at a temperature of not higher than 1000° C. whereas the second layer forming step is carried out at a temperature of not lower than 1000° C.
